(19) United States
(12) Patent Application Publication
(10) Pub. No.: US 2010/0078719 A1
(43) Pub. Date: Apr. 1, 2010

(54) SEMICONDUCTOR DEVICE

(76) Inventor: Kazuma YOSHIDA, Kyoto (JP)

Correspondence Address: MCDERMOTT WILL & EMERY LLP, 600 13TH STREET, NW, WASHINGTON, DC, 20005-3096, US

(21) Appl. No.: 12/570,795

(22) Filed: Sep. 30, 2009

(30) Foreign Application Priority Data
Sep. 30, 2008 (JP) 2008-254051

(51) Int. Cl. H01L 27/088

(52) U.S. Cl. 257/334; 257/652; 257/E27.06

(57) ABSTRACT

A semiconductor device in which a desired device is formed, comprising a semiconductor substrate having a first impurity region of a first conductivity type provided around an edge of a region in which the desired device is formed, and a second impurity region of the first conductivity type provided in a scribe region of the semiconductor substrate; wherein a channel stopper is formed between the first impurity region and the second impurity region.

### BACKGROUND OF THE INVENTION

1. Field of the Invention

The present invention relates to a semiconductor device and, more particularly, to prevention of leakage from a chip edge in a semiconductor device, such as an insulated gate transistor having a trench structure.

2. Description of the Related Art

As a decrease in power consumption, sophistication of functionality, and speedup of electronic equipment, including a portable phone, are pursued, demands for a decrease in power consumption and speedup of a semiconductor device to be incorporated in the electronic equipment are also growing in recent years. In general, transistors used in a load switch, a DC-DC converter, and the like, of the electronic equipment are also requested to have small ON resistance in order to meet the demands. In order to reduce the ON resistance of the transistor, one method is to miniaturize individual devices, thereby increasing a density of transistor per unit area. Specifically, in a vertical MOSFET in which gate electrodes are made in trenches, trenches making up transistors are arranged in a stripe pattern, thereby miniaturizing the width of each of the trenches and reducing a pitch between adjacent trenches. The density of transistor can thus be increased.

One example is that plural trenches are laid in a semiconductor chip and that MOSFETs are arranged in these trenches. In this structure, a gate pad is made in a part of a surface of a semiconductor chip. Gate electrodes made by filling the trenches with polycrystalline silicon are connected to the gate pad by means of gate wires made along an edge of the semiconductor chip (JP-A-2007-48769).

In such a MOSFET, a p⁻ region is made as an embedded and diffused region 11t in a scribe region S as illustrated by way of example in FIGS. 11 and 12. Herein, the scribe region S is a region for cutting out the device in time of dicing.

As mentioned above, the related-art semiconductor device having a stripe-like trench gate encounters a problem of leakage current flowing through an inverse region formed between a diffused region 11t formed in a scribe region S along an edge and an embedded and diffused region 11s making up a source region.

This problem has particularly become serious as the withstand voltage of an element becomes higher.

### SUMMARY OF THE INVENTION

The present invention has been conceived in light of the circumstance and aims at providing a highly-reliable semiconductor device that reduces a leakage current in a semiconductor device, such as a MOSFET, in which embedded and diffused regions 11d are made in a scribe region S along an edge.

In order to solve the problem, a semiconductor device of the present invention is one in which a channel stopper made of; for instance, an interconnection layer, is formed on a surface of a substrate between an embedded and diffused region in a scribe region and an embedded and diffused region laid along an edge of a device, thereby inhibiting formation of an inverse region which would become a channel. For instance, after a high-temperature reverse bias test, an inversion region that will become a channel is made between an embedded and diffused region of the scribe region and the embedded and diffused region laid along the edge of the device. By the foregoing configuration, a channel stopper made of an interconnection layer is made on the surface of the substrate, thereby inhibiting formation of an inversion region. Occurrence of leakage after a high-temperature reverse bias test is considered to be attributable to formation of an inversion region, which will become a channel, between the embedded and diffused region of the scribe region and the embedded and diffused region laid along the edge of the device by application of a temperature and a bias voltage. A conceivable direct cause is that movable ions in a thermal oxide film made on an impurity region (an N⁻-layer), which will become a channel region, are induced by the test, to thus assume a negative electric potential and enter a state in which an inversion layer is easily formed. The present invention prevents the cause, thereby inhibiting occurrence of the leakage.

That is, this invention provides with a semiconductor device comprising a semiconductor substrate in which a desired device is formed and having a first impurity region of a first conductivity type provided around an edge of a region in which the desired device is formed, and a second impurity region of the first conductivity type provided in a scribe region of the semiconductor substrate, wherein a channel stopper is formed between the first impurity region and the second impurity region.

Preferably, an interconnection layer that will become the channel stopper is formed from the same layer as a periphery wing such as aluminum wiring.

Also, this channel stopper further comprises a polycrystalline silicon ring connected to the interconnection layer formed from the same layer as the periphery wing such as aluminum wiring.

Also, if this channel stopper slightly protrudes from the embedded and diffused region in the scribe region, it is effective.

Also preferably, this interconnection layer that will become the channel stopper is electrically connected to a back surface electrode at a corner portion of the semiconductor chip.

Also, a semiconductor region of opposite conductivity is formed on the embedded and diffused region of the scribe region. This semiconductor region may as the channel stopper.

That is, the semiconductor device is wherein the semiconductor substrate has a semiconductor layer of a desired impurity concentration and includes trench gates made by filling a plurality of stripe-like trenches made in the semiconductor layer with a conductor layer through a gate oxide film; an insulation film covering the surface of the semiconductor layer; a source electrode formed through a source contact opening so as to penetrate through the insulation film; a source region that is formed in the semiconductor layer and that serves as a body region electrically connected to the source electrode and as the first impurity region; a gate peripheral line connected to the trench gates along edges of the trench gates; a gate electrode which is in the same plane where the source electrode is provided, which is formed at a position spaced apart from the source electrode, and which is connected to the gate peripheral line; and a drain electrode, and wherein the second impurity region is formed in a neighborhood of an edge of the source region at a predetermined space, thereby forming the scribe region.

The channel stopper may be made of the same layer as that of the source electrode. The channel stopper is formed from two layers, and a lower layer may be formed from the same layer as that of the trench gate.

As described in detail above, the structure of the present invention, a channel stopper is formed between the embedded and diffused region laid along the edge of the scribe region and the diffused region laid along the edge of the device, and hence formation of an inversion region is inhibited, and occurrence of leakage can be prevented. Further, by use of the channel stopper using wiring, formation of an inversion layer is inhibited by changing only a pattern at the time of patterning of an interconnection layer, so that occurrence of a leakage current and deterioration of a withstand voltage can be prevented.

Further, a polycrystalline silicon layer situated below the interconnection layer, such as aluminum wiring, is laid in an area where a channel is easy to form, whereby the effect of the channel stopper can be further enhanced.

### BRIEF DESCRIPTION OF THE DRAWINGS

FIG. 1 is a conceptual plan view of a characteristic portion of a trench MOSFET of a first embodiment of the present invention;

FIG. 2 is a cross-sectional view taken along line A-A shown in FIG. 1;

FIG. 3 is a cross-sectional view taken along line B-B shown in FIG. 1;

FIG. 4 is a general plan view of an entirety of the trench MOSFET of the first embodiment of the present invention;

FIG. 5 is a cross-sectional view taken along line A′-A′ shown in FIG. 4;

FIG. 6 is a process chart of manufacture of the trench MOSFET of the first embodiment of the present invention;

FIG. 7 shows a result of measurement of a relationship between the length of a projection of a channel stopper electrode and a leakage current;

FIG. 8 is a cross-sectional view of a trench MOSFET of a second embodiment of the present invention taken along line A-A;

FIG. 9 is a cross-sectional view of the trench MOSFET taken along line B-B;

FIG. 10 is a cross-sectional view of a trench MOSFET of a third embodiment of the present invention taken along line A-A;

FIG. 11 is a cross-sectional view of a related-art example trench MOSFET taken along line A-A; and

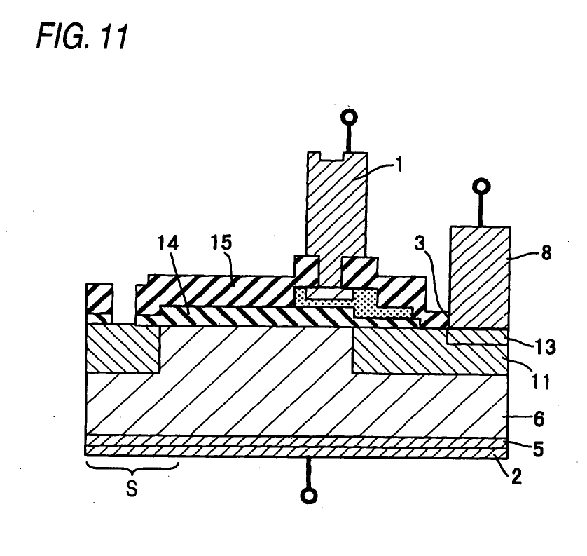

FIG. 12 is a cross-sectional view of a related-art example trench gate MOSFET taken along line B-B.

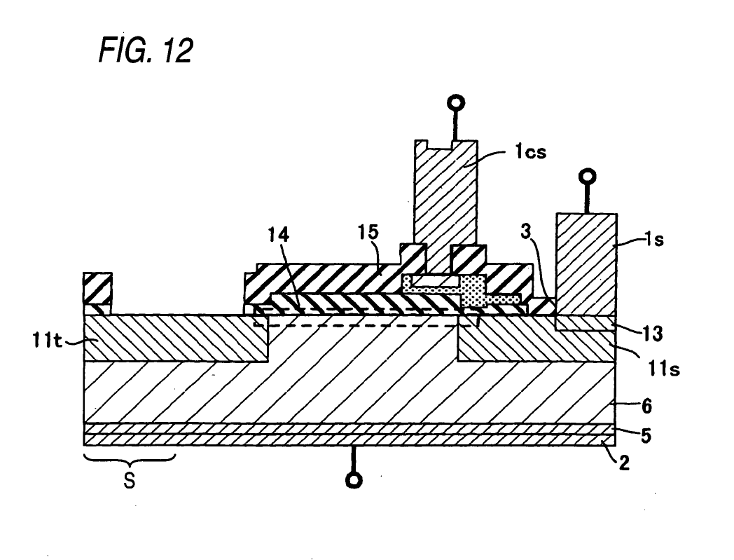

### DESCRIPTION OF THE PREFERRED EMBODIMENTS

### First Embodiment

Embodiments of the present invention will be described in detail by reference to the drawings.

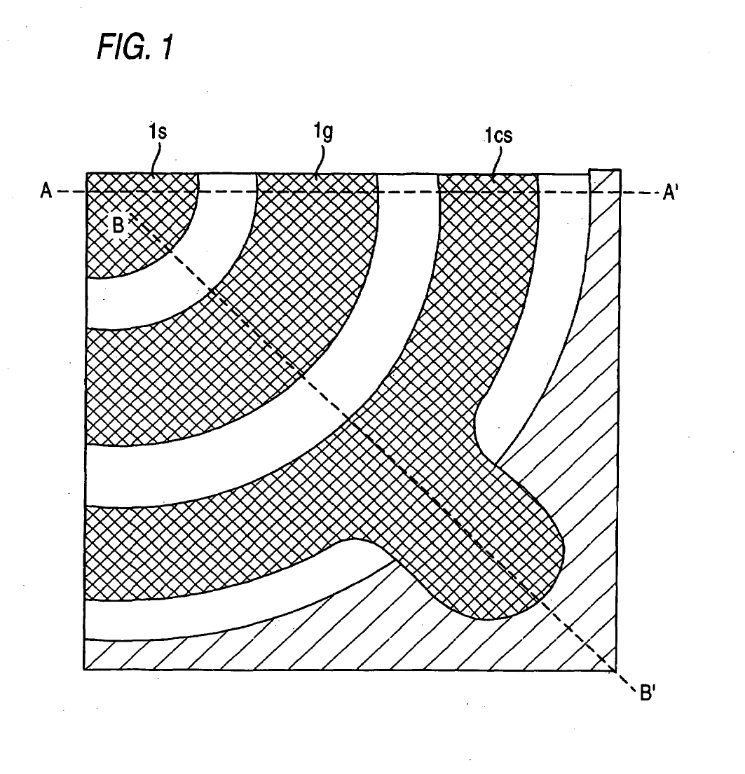

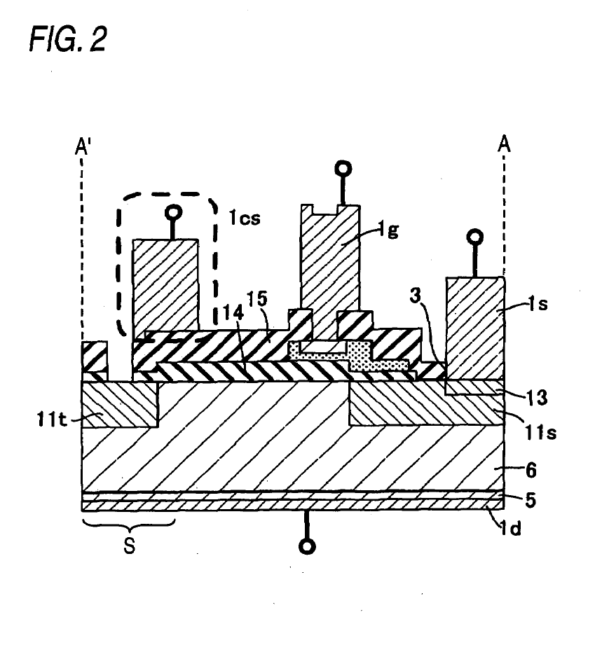

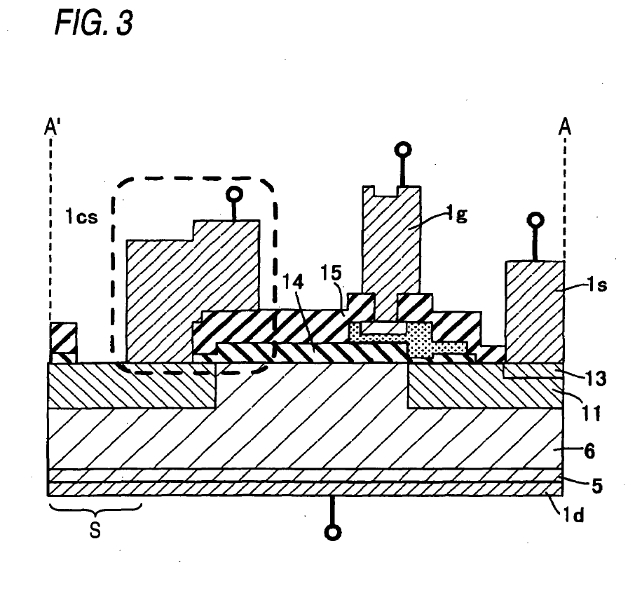

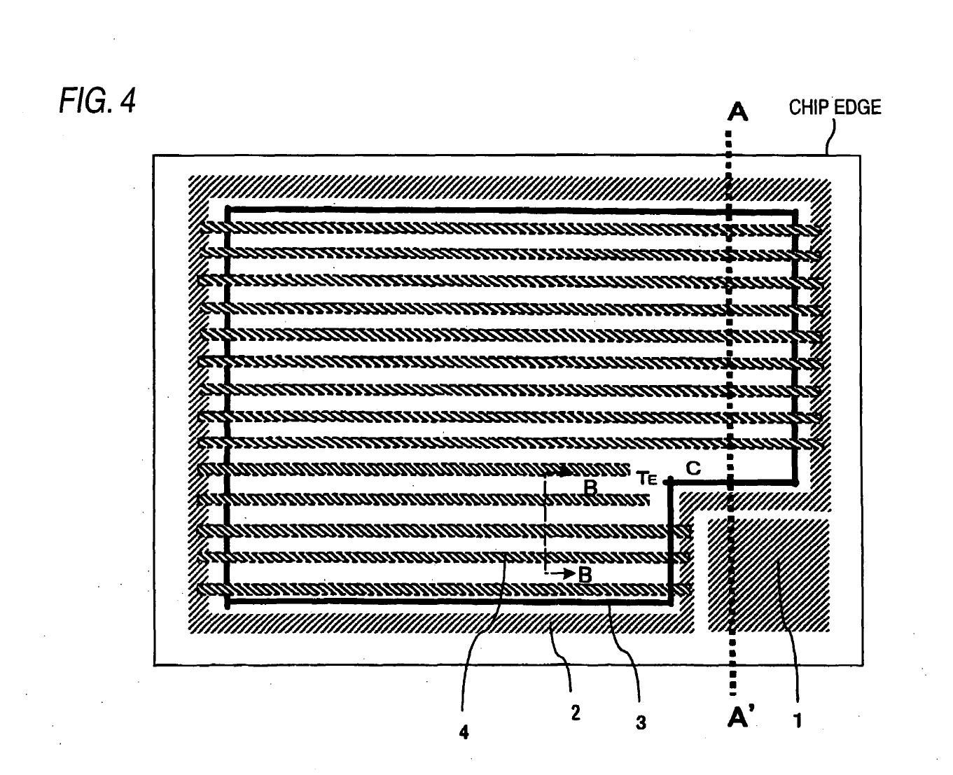

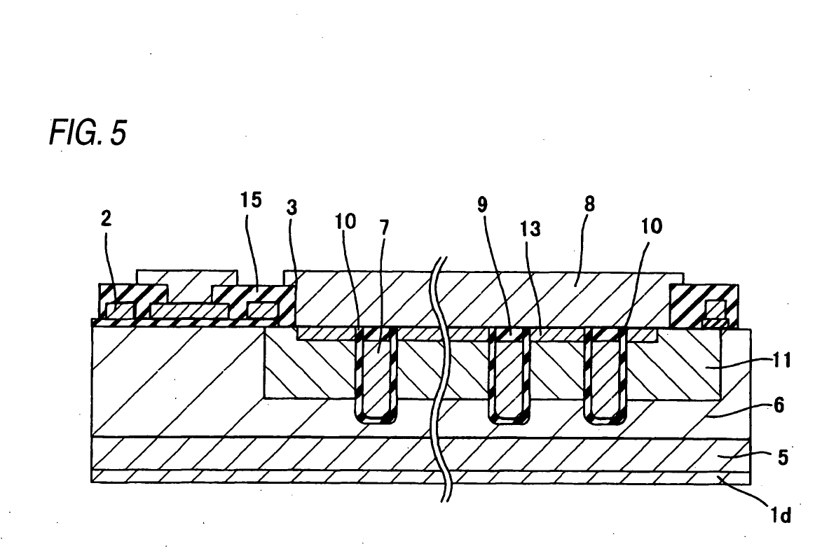

FIG. 1 is a conceptual plan view of a characteristic portion of a trench MOSFET of an embodiment of the present invention; FIG. 2 is a cross-sectional view taken along line A-A′ shown in FIG. 1; FIG. 3 is a cross-sectional view taken along line B-B′ shown in FIG. 1; FIGS. 4 and 5 are conceptual plan views showing the entirety of the trench MOSFET; and FIG. 5 is a cross-sectional view taken along line A-A′ shown in FIG. 4.

As shown in FIGS. 1 through 3, a trench MOSFET of the present embodiment is characterized in that a channel stopper electrode 1cs using aluminum wiring is formed between a P⁻ region serving an embedded and diffused region 11t laid along an edge of a scribe region S and a P⁻ region serving as a diffused region 11s laid along an edge of the trench MOSFET. The channel stopper electrode 1cs overlaps the embedded and diffused region 11t laid along the edge of the scribe region S by 5 μm or more and is structured so as to have the same electric potential as that of a drain electrode 1d. By this configuration, there is yielded a characteristic of formation of an inversion layer being hindered by changing only a pattern at the time of patterning of an interconnection layer, thereby preventing generation of a leakage current and deterioration of a withstand voltage. The channel stopper electrode 1cs is structured so as to have the same electric potential as that of the drain electrode 1d. The diffused region 11s laid along the edge of the trench MOSFET corresponds to a first impurity region, and the embedded and diffused region 11t corresponds to a second impurity region. The scribe region S is located outside of the first impurity region for cutting out the device.

An ordinary configuration is employed for the other area of a semiconductor chip. As shown in FIGS. 4 and 5, trenches 4 are formed in a semiconductor layer, and by filling the trenches 4 with polycrystalline silicon through a gate oxide film 10 made of silicon oxide trench gates 7 are formed. A source region 13 is formed so as to contact the trench gates 7 and have a given depth at either end of each of the trench gates 7, and is electrically connected to a source electrode 1s (a source pad) at a source contact opening 3.

The drain region is made up of an N-type epitaxial layer 6 and an N-type substrate 5, and an entire rear surface of a semiconductor chip makes up a drain electrode 1d.

Specifically, the semiconductor chip has: the trench gates 7 made by filling the plurality of stripe-like trenches 4, which are made in the N-type epitaxial layer 6 formed over a surface of the N-type silicon substrate 5 through the gate oxide film 10, with a polycrystalline silicon layer (a conductor layer); an insulation film 15 made of a silicon oxide film covering the surface of the semiconductor layer; the source electrode 1s made so as to contact the source region 13 through the source contact opening 3 made in the insulation film 15; a gate peripheral line 2 connected to the trench gates 7 at their edges; a gate electrode 1g that is in the same plane where the source electrode 1s is provided and that is made at a position spaced apart from the source electrode and connected to the gate peripheral line 2; and a drain electrode 1d formed on the rear of the silicon substrate.

As shown in FIG. 4, the gate peripheral line 2 is laid between the area where the gate electrode 1g is made and the source electrode is, so as to surround the area where the gate electrode 1g is made, as well as along the edge of the chip. Therefore, it is possible to reduce interconnection resistance by means of further shortening a power feed line for feeding power to the trench gates.

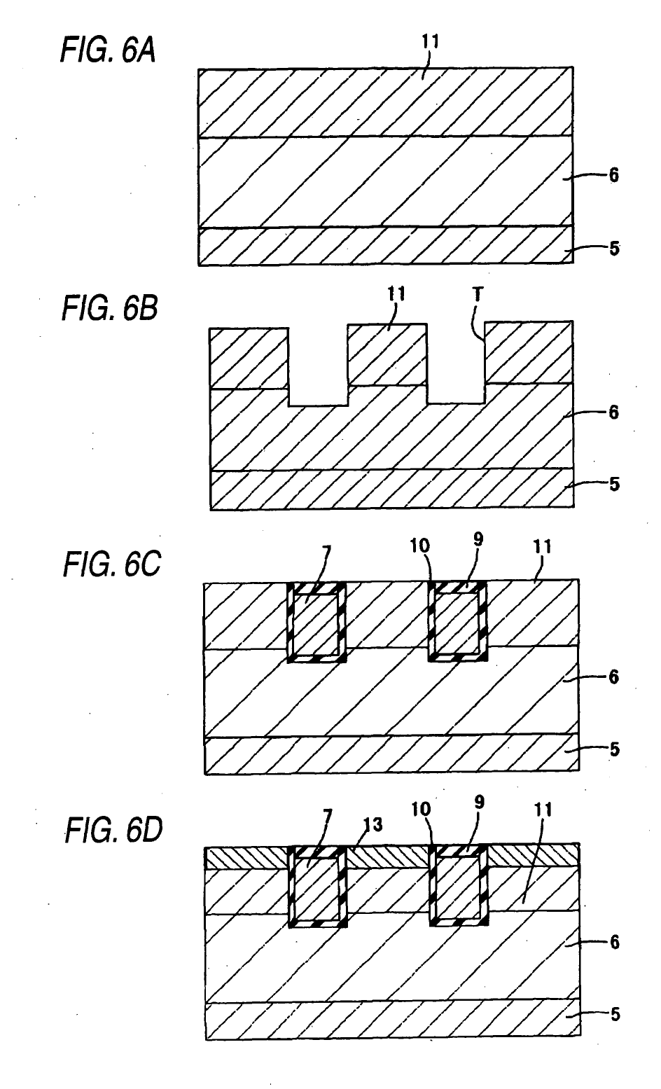

A method for manufacturing the semiconductor device of the present invention wilt now be described by reference to FIG. 6. The manufacturing method is totally identical with the related-art manufacturing method in connection with manufacturing processes for forming trenches.

As shown in FIG. 6A, a method for manufacturing an N-type MOSFET having a stripe-shaped trench gate structure uses an N⁺-type silicon wafer as the semiconductor substrate 5, and an N⁻-type epitaxial layer 6 is formed on the surface of the silicon wafer. A P-type well layer 11 is made within the N⁻-type epitaxial layer 6.

As shown in FIG. 6B, the trenches 4 are made in the surface of the N⁻-type epitaxial layer 6 on which the P-type well layer 11 is formed, by means of photolithography and dry etching.

Subsequently, as shown in FIG. 6C, the gate oxide film 10 having a thickness of about 30 nm is formed on sidewalls of the respective trenches by means of thermal oxidation. Subsequently, a polycrystalline silicon film (a trench gate) 7 is deposited on the inside of the trenches 4 by means of CVD, and the polycrystalline silicon 7 is doped with impurities. Subsequently, unwanted portions have been removed from the polycrystalline silicon by means of chemical-mechanical polishing (CMP) or etching back, a silicon oxide film 9 is made over the polycrystalline silicon 7 by means of thermal oxidation.

In order to make an N-type diffused layer which will become the source region 13 and a P-type diffused layer which will become a body region 12, the P-type well layer 11 is implanted with phosphor and boron impurities by means of ion implantation as shown in FIG. 6D.

An insulation film and a protective film are then deposited on the surface of the semiconductor chip, and the source contact opening 3 is formed in order to establish electrical conduction between the source electrode 1s and the source region 13. An aluminum thin film is made, thereby making a metal interconnection making up the source electrode 1s and the channel stopper electrode 1cs. Thus, when the aluminum thin film is patterned, the semiconductor device shown in FIGS. 1 through 5 is fabricated by changing only a mask pattern.

By the configuration, the channel stopper electrode 1cs using aluminum wiring is formed between the P⁻ region serving the embedded and diffused region 11t laid along the edge of the scribe region S and the P⁻ region serving as the diffused region 11s laid along the edge of the trench MOSFET. Formation of an inversion layer can be hindered by changing only a pattern at the time of patterning of an interconnection layer. Accordingly, deterioration of a withstand voltage and a leakage characteristic can be prevented by changing only the aluminum interconnection pattern.

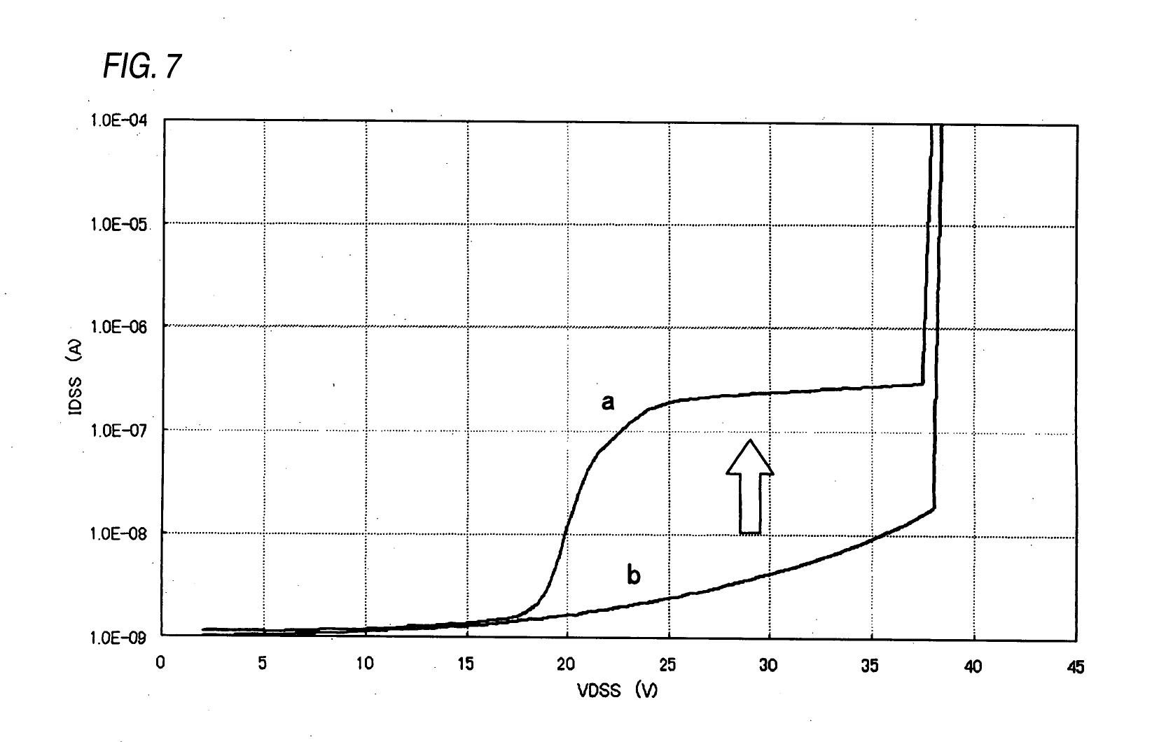

FIG. 7 shows a result of measurement of a relationship between a withstand voltage and a degree at which the channel stopper electrode made of aluminum wiring extends to the embedded and diffused region 11t laid along the edge of the scribe region S. A curve “a” designates a withstand voltage characteristic achieved when no channel stopper electrode is provided, and a curve “b” designates a withstand voltage characteristic achieved when a channel stopper electrode is provided. After a high-temperature reverse bias test, a leakage current (l_{DSS}) from the device increased from the neighborhood of V_{DSS} 18V, and a stepped characteristic was exhibited. Saturation tendency appeared after an increase in current, but withstand voltage fluctuations did not appear. It is understood from the results that a current leakage can be inhibited by presence of the channel stopper electrode.

### Second Embodiment

A second embodiment of the present invention will now be described.

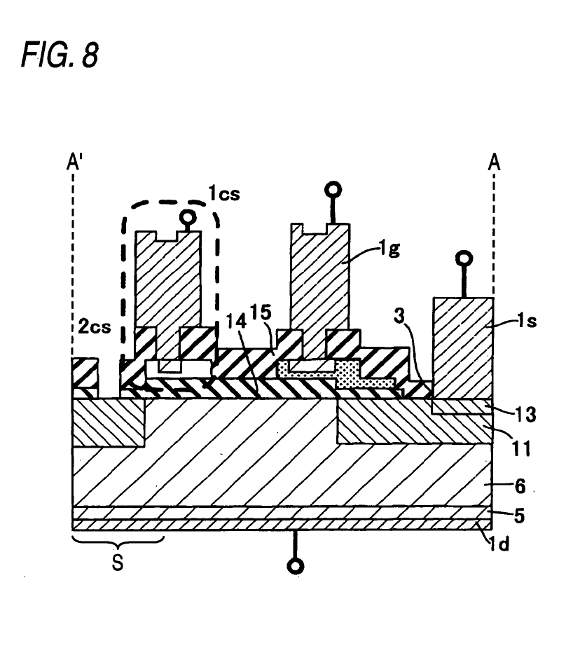

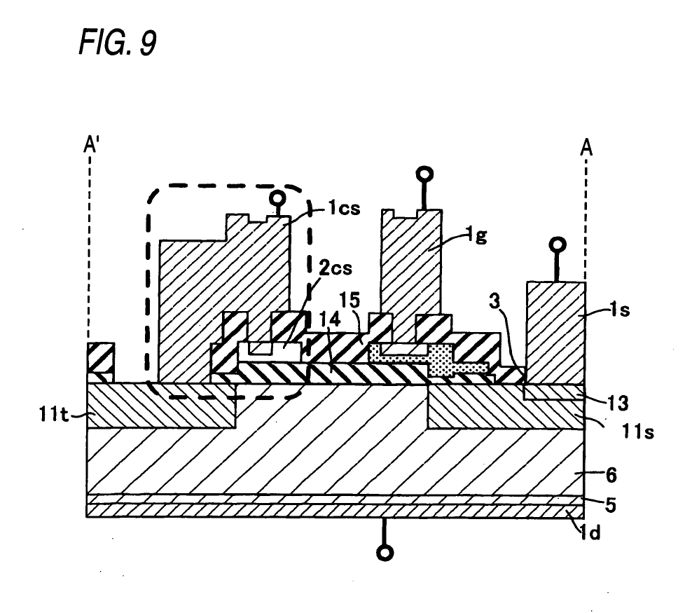

As shown in FIGS. 8 and 9, the second embodiment is characterized in that, in addition to the channel stopper electrode 1cs described in connection with the first embodiment, a channel stopper layer 2cd is laid below the channel stopper electrode (aluminum wiring), wherein the channel stopper layer 2cd is connected to the trench gate 7, is made in the same processes through which the gate peripheral line 2 is formed from polycrystalline silicon, and is formed from polycrystalline silicon; and that the channel stopper layer 2cd is arranged in a channel region between the P⁻-region (the source region 11s) serving as the diffused region 11s laid along the edge of the trench MOSFET and the P⁻-region serving as the embedded and diffused region 11t laid along the edge of the scribe region S so as to oppose each other by way of the insulation film 14, thereby further enhancing a channel stopper effect. Here, reference numeral 8 designates a highly doped contact region for enhancing contactability.

### Third Embodiment

A third embodiment of the present invention will now be described.

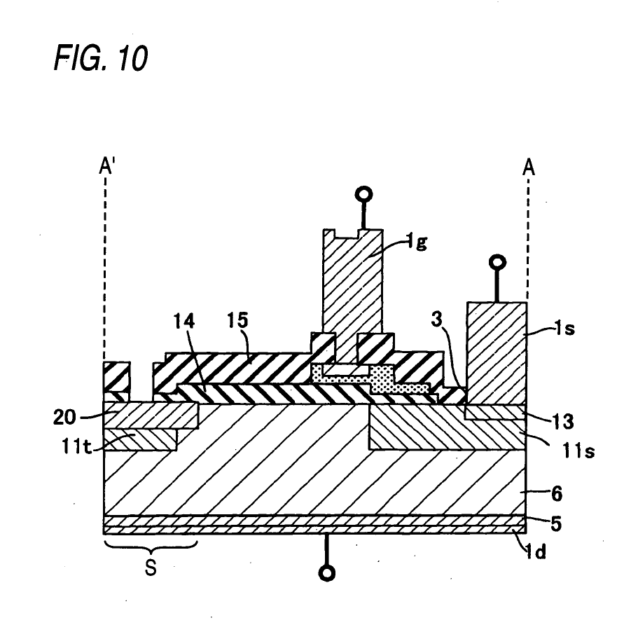

As shown in FIGS. 8 and 9, in the second embodiment, in addition to the channel stopper electrode 1cs described in connection with the first embodiment, the channel stopper layer 2cd is laid below the channel stopper electrode, wherein the channel stopper layer 2cd is connected to the trench gate 7, is made in the same processes through which the gate peripheral line 2 is formed from polycrystalline silicon, and is formed from polycrystalline silicon. However, as shown in FIG. 10, the present embodiment is characterized in that a channel stopper interior layer 20 made of an n-type well which is a semiconductor region of reverse conductivity type is formed in the P⁻-region serving as the embedded and diffused region 11t laid along the edge of the scribe region S. FIG. 10 is a cross section corresponding to a cross section taken along line A-A shown in FIG. 1.

Even in the configuration, an inversion layer is made in a channel region between the P⁻-region (the source region 11s) serving as the diffused region 11s laid along the edge of the trench MOSFET and the P⁻-region serving as the embedded and diffused region 11t laid along the edge of the scribe region S, thereby preventing occurrence of a current leakage.

The channel stoppers described in connection with the first through third embodiments can simultaneously be provided in number of two or more.

In the present embodiments, the trench MOSFET has been described. However, the semiconductor chip is not limited to a MOSFET, and the present invention can also be applied to another element having a trench structure, such as a trench capacitor and DRAM. In particular, the present invention is applicable to a device having an embedded and diffused region provided for the purpose of making a test contact along an edge of a scribe region S. Since a channel stopper using wiring is made between the embedded, diffused region laid along the edge of the scribe region S and the diffused region laid along the edge of the device, formation of an inversion layer can be inhibited by changing only a pattern at the time of patterning of an interconnection layer, so that occurrence of a leakage current and deterioration of a withstand voltage can be prevented.

The structure yields a characteristic of the capability of inhibiting formation of an inversion layer by changing only a pattern at the time of patterning of an interconnection layer and preventing occurrence of a leakage current and deterioration of a withstand voltage. The channel stopper electrode 1cs and the channel stopper layer 2cs are formed so as to have the same electric potential as that of the drain electrode 1d.

As has been described above, according to the present invention, occurrence of a leakage current can be inhibited even when a withstand voltage is enhanced. Hence, the present invention is effective for an application, such as a highly reliable electronic device to be mounted in a vehicle.

What is claimed is:

1. A semiconductor device, comprising:
a semiconductor substrate in which a desired device is formed and having a first impurity region of a first conductivity type provided around an edge of a region in which the desired device is formed, and a second impurity region of the first conductivity type provided in a scribe region of the semiconductor substrate; wherein a channel stopper is formed between the first impurity region and the second impurity region.

2. The semiconductor device according to claim 1, wherein the channel stopper is a channel stopper interconnection layer formed on the semiconductor substrate and between the first impurity region and the second impurity region in the scribe region.

3. The semiconductor device according to claim 1, wherein the channel stopper is a channel stopper layer formed on a surface of the semiconductor substrate through an insulation film and between the first impurity region and the second impurity region.

4. The semiconductor device according to claim 3, wherein the channel stopper layer includes an aluminum wiring.

5. The semiconductor device according to claim 3, wherein the channel stopper layer includes an aluminum wiring and a polycrystalline silicon layer formed below the aluminum wiring.

6. The semiconductor device according to claim 1, wherein the channel stopper layer has a third impurity region of a second conductivity type formed in an area opposing at least the first impurity region in the scribe region.

7. The semiconductor device according to claim 1, wherein:
the semiconductor substrate has:
a semiconductor layer of a desired impurity concentration and includes trench gates made by filling a plurality of stripe-like trenches made in the semiconductor layer with a conductor layer through a gate oxide film;
an insulation film covering the surface of the semiconductor layer;
a source electrode formed through a source contact opening so as to penetrate through the insulation film;
a source region that is formed in the semiconductor layer and that serves as a body region electrically connected to the source electrode and as the first impurity region;
a gate peripheral line connected to the trench gates along edges of the trench gates; and
a gate electrode which is in the same plane where the source electrode is provided, which is formed at a position spaced apart from the source electrode, and which is connected to the gate peripheral line; and a drain electrode, and
wherein the second impurity region is formed in a neighborhood of an edge of the source region at a predetermined space, thereby forming the scribe region.

8. The semiconductor device according to claim 7, wherein the channel stopper is composed of the same layer as that of the source electrode.

9. The semiconductor device according to claim 7, wherein the channel stopper is formed from two layers, and a lower layer of the two layers is formed from the same layer as that of the trench gate.

10. The semiconductor device according to claim 7, wherein the channel stopper is a third impurity region of second conductivity type formed so as to include an area opposing the source region in the second impurity region.

11. The semiconductor device according to claim 7, wherein the channel stopper is electrically connected to the drain electrode at a corner of the semiconductor substrate.
